(19) United States
(12) Patent Application Publication
(10) Pub. No.: US 2025/0066909 A1
(43) Pub. Date: Feb. 27, 2025

(54) SEAL STRUCTURE, CHAMBER, SUBSTRATE PROCESSING APPARATUS, AND METHOD OF INSTALLING SEAL MATERIAL

(71) Applicant: Tokyo Electron Limited, Tokyo (JP)

(72) Inventor: Tsutomu HIROKI, Nirasaki City (JP)

(21) Appl. No.: 18/947,353

(22) Filed: Nov. 14, 2024

Related U.S. Application Data
(63) Continuation of application No. PCT/JP2023/017729, filed on May 11, 2023.

(30) Foreign Application Priority Data
May 25, 2022 (JP) 2022-085102

(51) Int. Cl. C23C 16/44

(52) U.S. Cl. CPC C23C 16/4409

(57) ABSTRACT

A seal structure, includes: a groove formed to be wider than a seal material; a pressing member arranged on one side in a width direction of the groove in a region in the groove so as to adjust a position in the width direction of the groove, and including an eaves portion, which extends toward the other side in the width direction of the groove to form a slit through which an inside of the groove communicates with an outside of the groove and presses the seal material into the groove; and a fixing mechanism configured to fix the pressing member.

### CROSS-REFERENCE TO RELATED APPLICATION

This application is a bypass continuation application of International Patent Application No. PCT/JP2023/017729 having an international filing date of May 11, 2023 and designating the United States, the international application being based upon and claiming the benefit of priority from Japanese Patent Application No. 2022-085102 filed on May 25, 2022, the entire contents of which are incorporated herein by reference.

### TECHNICAL FIELD

The present disclosure relates to a seal structure, a chamber, a substrate processing apparatus, and a method of installing a seal material.

### BACKGROUND

Patent Document 1 discloses a seal structure between a lower chamber and an upper chamber as a seal structure between a processing region inside a substrate processing apparatus and an external region outside the substrate processing apparatus. In this seal structure, a dovetail groove is formed on a seal surface of the lower chamber, and a seal member such as an O-ring is fitted into the dovetail groove.

### PRIOR ART DOCUMENTS

### Patent Documents

Patent Document 1: Japanese patent laid-open publication No. 2020-196053

### SUMMARY

According to one embodiment of the present disclosure, there is provided a seal structure including: a groove formed to be wider than a seal material; a pressing member arranged on one side in a width direction of the groove in a region in the groove so as to adjust a position in the width direction of the groove, and including an eaves portion, which extends toward the other side in the width direction of the groove to form a slit through which an inside of the groove communicates with an outside of the groove and presses the seal material into the groove; and a fixing mechanism configured to fix the pressing member.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram schematically illustrating an outline of the configuration of a film forming apparatus as a substrate processing apparatus according to an embodiment, showing a cross-section of a part of the film forming apparatus.

FIG. 2 is a top view of a chamber body.

FIG. 3 is a partially enlarged perspective cross-sectional view of the chamber body.

FIG. 4 is a cross-sectional view of a non-fixed groove.

FIG. 5 is a cross-sectional view of a fixed groove.

FIG. 6 is a partially enlarged perspective view of the chamber body.

FIG. 7 is an explanatory diagram of a fixing mechanism.

FIG. 8 shows another example of a seal structure.

FIG. 9 is a diagram showing another example of a protrusion.

FIG. 10 is a diagram showing another example of a fixing mechanism for a pressing member.

FIG. 11 is a diagram showing another example of the fixing mechanism for the pressing member.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of a semiconductor device, various substrate processing processes, such as a film formation process for forming a predetermined film, are performed on a substrate such as a semiconductor wafer (hereinafter referred to as a “wafer”). These substrate processing processes are performed by a substrate processing apparatus, specifically, in a state in which the substrate is accommodated in a reduced-pressure chamber of the substrate processing apparatus.

In addition, the substrate processing apparatus has a seal structure that isolates an internal reduced-pressure atmosphere of the substrate processing apparatus from an external atmosphere of the substrate processing apparatus. In this seal structure, the internal reduced-pressure atmosphere is isolated from the external atmosphere by a seal material, such as an O-ring, installed between two members that form the substrate processing apparatus. The seal material is fixed in a groove formed on a seal surface of one of the two members. In addition, a dovetail groove may be adopted to fix the seal material in the groove. However, in the case of the dovetail groove, since it is necessary to accommodate the seal material by pushing the seal material into the dovetail groove, the seal material may be twisted when the seal material is accommodated in the groove. It is difficult to eliminate this twist after the seal material is accommodated in the groove. In a twisted state of the seal material, there is a risk that a lifespan of the seal material etc. may be adversely affected.

Therefore, a technique of the present disclosure fixes the seal material in the groove without twisting.

Hereinafter, a seal structure, a chamber, a substrate processing apparatus, and a method of installing a seal material according to an embodiment will be described with reference to the drawings. In this specification and the drawings, elements having substantially the same functional configuration are given the same reference numerals to avoid redundant explanation.

### <Film Forming Apparatus>

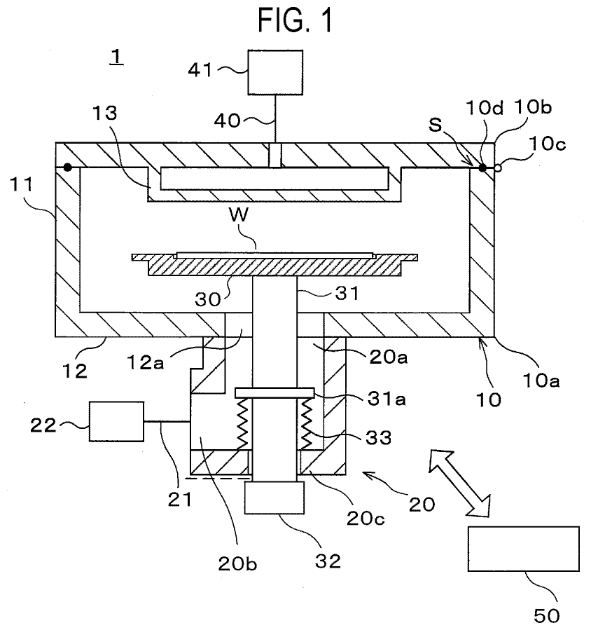

FIG. 1 is an explanatory diagram schematically illustrating an outline of the configuration of a film forming apparatus as a substrate processing apparatus according to an embodiment, showing a cross-section of a part of the film forming apparatus.

A film forming apparatus 1 of FIG. 1 is configured to perform a film forming process on a wafer W as a substrate and form, for example, a metal film on the wafer W.

The film forming apparatus 1 has a chamber 10. The chamber 10 accommodates the wafer W therein and is configured to be capable of reducing pressure. The chamber 10 has a chamber body 10a and a cover member 10b.

The chamber body 10a is formed, for example, in a cylindrical shape (specifically, a rectangular cylindrical shape) with an open upper portion and a bottom. The chamber body 10a is formed, for example, of a ceramic material. The chamber body 10a is formed by molding. The chamber body 10a may be provided with a heating mechanism (e.g., a resistance heating heater or a high-temperature refrigerant flow path) for heating the chamber body 10a.

A side wall 11 of the chamber body 10a is provided with a loading/unloading port (not shown) for the wafer W, and the loading/unloading port is provided with a gate valve (not shown) for opening and closing the loading/unloading port.

An exhaust port 12a is formed in a bottom wall 12 of the chamber body 10a. An accommodator 20, which accommodates a bellows 33 to be described later, is connected to the bottom wall 12 so that an upper opening 20a of the accommodator 20 communicates with the exhaust port 12a. The accommodator 20 has openings 20a and 20b at upper and side portions of the accommodator 20, respectively, and the openings 20a and 20b communicate with each other. One end of an exhaust pipe 21 is connected to the side portion of the accommodator 20 so that the inside of the chamber 10 is exhausted through the openings 20a and 20b. The other end of the exhaust pipe 21 is connected to an exhaust mechanism 22 having a vacuum pump or the like.

The cover member 10b closes an upper opening of the chamber body 10a. The cover member 10b is formed, for example, in a rectangular shape when viewed in plan. The cover member 10b is formed of, for example, a ceramic material. A hinge 10c is installed at one end of the chamber body 10a in a horizontal direction (a right end in FIG. 1). The cover member 10b is pivotally supported by the hinge 10c and is configured to open and close the upper opening of the chamber body 10a by the hinge 10c.

An O-ring 10d is installed between the chamber body 10a and the cover member 10b as a seal material to maintain airtightness. In other words, the chamber 10 has a seal structure S that isolates a reduced-pressure atmosphere inside the chamber 10 from an atmosphere outside the chamber 10 using the O-ring 10d as the seal material. A more specific configuration of the seal structure S will be described later.

In the chamber 10, a stage 30 on which the wafer W is horizontally placed is installed and the stage 30 has a circular shape when viewed in plan. A heater (not shown) for heating the wafer W is installed inside the stage 30. An upper end of a support member 31 extending in a vertical direction is connected to the center of a lower surface side of the stage 30 so that the support member 31 penetrates the bottom wall 12 of the chamber body 10a through the exhaust port 12a of the bottom wall 12 and further penetrates a bottom wall 20c of the accommodator 20. A lower end of the support member 31 is connected to a lifting mechanism 32. The stage 30 can be moved up and down between a first position at an upper side and a second position at a lower side by driving of the lifting mechanism 32 controlled by a controller 50 to be described later.

The first position is a processing position at which the wafer W is processed. The second position is a standby position at which the stage 30 waits while the wafer W is delivered between a transfer mechanism (not shown) for the wafer W that enters the chamber 10 from the aforementioned loading/unloading port (not shown) of the chamber 10 and a delivery pin (not shown) installed below in the chamber 10.

Furthermore, the support member 31 is provided with a flange 31a. The bellows 33 is installed so as to surround an outer periphery of the support member 31 between a lower surface of the flange 31a and an upper surface of the bottom wall 20c of the accommodator 20. Because this bellows 33 is installed, loss of airtightness of the chamber 10 caused by a portion penetrated by the support member 31 in the bottom wall 20c of the accommodator 20 is prevented.

Furthermore, in the cover member 10b of the chamber 10, a supply 13 of a film forming gas as a process gas is installed so as to face the stage 30. The supply 13 supplies the film forming gas into the chamber 10. The film forming gas supplied by the supply 13 is, for example, a film forming gas for forming a metal film. One end of a supply pipe 40 is connected to the supply 13. The other end of the supply pipe 40 is connected to a supply mechanism 41 having a flow rate adjustment valve (not shown) for adjusting the flow rate of the film forming gas from a gas supply source.

The film forming apparatus 1 configured as described above is provided with the controller 50 as shown in FIG. 1. The controller 50 is configured by a computer equipped with a processor, such as a CPU, or a memory and has a program storage portion (not shown). The program storage portion stores a program for implementing wafer processing in the film forming apparatus 1. The program has been recorded in a computer-readable storage medium and may be installed in the controller 50 from the storage medium. The storage medium may be transitory or non-transitory.

### <Seal Structure S>

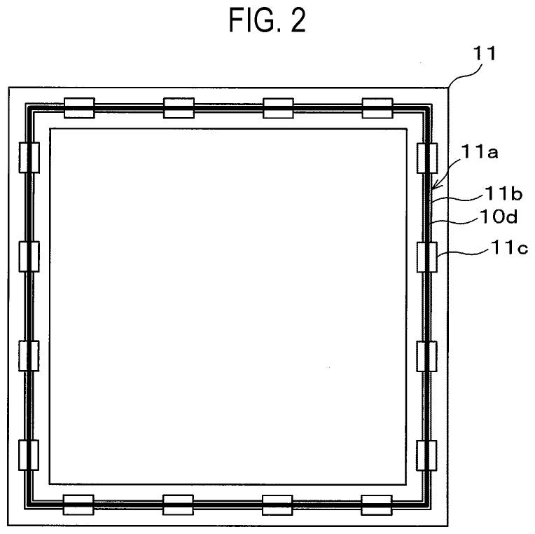

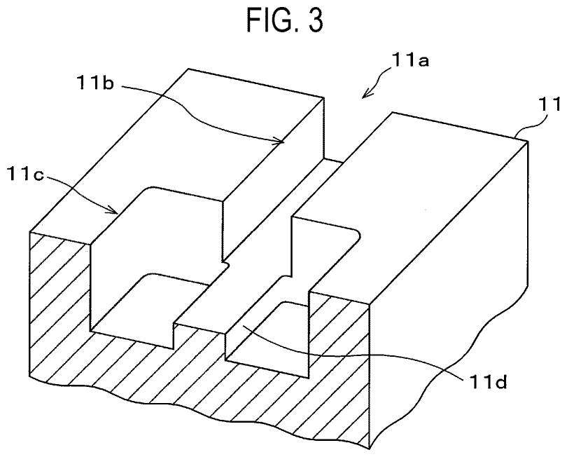

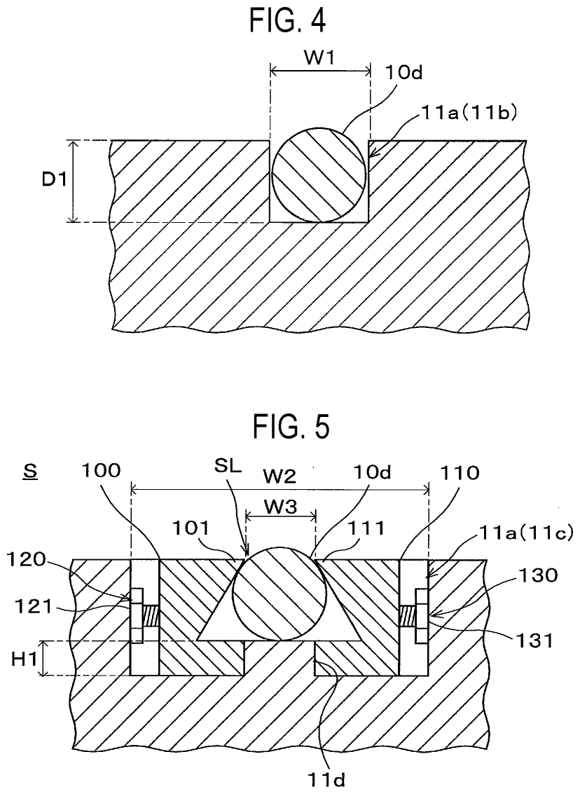

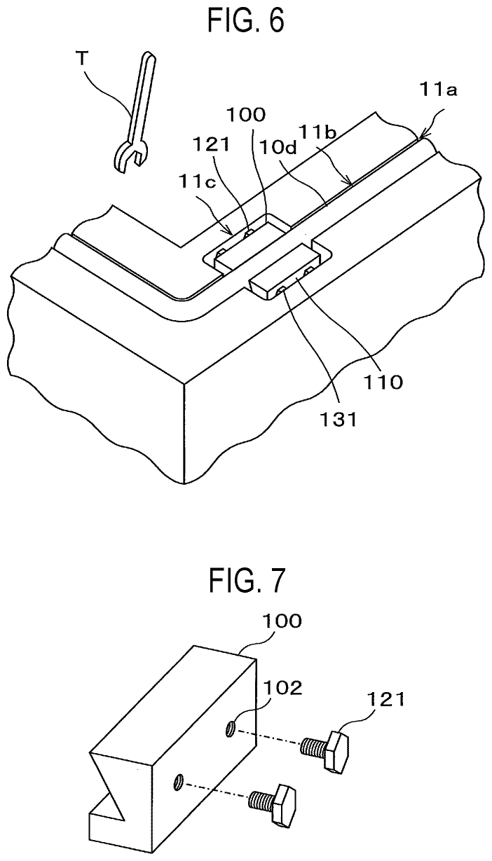

Next, an example of the configuration of the seal structure S will be described. FIG. 2 is a top view of the chamber body 10a, showing a state in which the O-ring 10d is accommodated in a groove 11a to be described later, but pressing members 100 and 110 to be described later are not arranged in a fixed groove 11c to be described later. FIG. 3 is a partially enlarged perspective cross-sectional view of the chamber body 10a, showing a state in which the O-ring 10d is not accommodated in the groove 11a and the pressing members 100 and 110 are not arranged in the fixed groove 11c. FIG. 4 is a cross-sectional view of a non-fixed groove 11b to be described later. FIG. 5 is a cross-sectional view of the fixed groove 11c. FIG. 6 is a partially enlarged perspective view of the chamber body 10a, showing a state in which the O-ring 10d is accommodated in the groove 11a and the pressing members 100 and 110 are arranged in the fixed groove 11c. FIG. 7 is an explanatory diagram of a fixing mechanism 120 to be described later.

As described above, the seal structure S isolates the reduced-pressure atmosphere inside the chamber 10 from the atmosphere outside the chamber 10 using the O-ring 10d. The O-ring 10d is arranged between two sealing surfaces, i.e., an upper surface of the side wall 11 of the chamber body 10a and a lower surface of a peripheral portion of the cover member 10b.

As shown in FIG. 2, the O-ring 10d is accommodated, for example, in the groove 11a formed on the upper surface of the side wall 11 of the chamber body 10a. The groove 11a is formed along the shape of the chamber 10 and is formed in, for example, a rectangular annular shape when viewed in plan.

In addition, the groove 11a includes the non-fixed groove 11b and the fixed groove 11c as shown in FIGS. 2 and 3.

The non-fixed groove 11b accommodates the O-ring 10d therein. However, the non-fixed groove 11b does not fix the O-ring 10d in the non-fixed groove 11b. The non-fixed groove 11b is, for example, as shown in FIG. 4, an angled groove having a flat bottom and vertical side surfaces.

Furthermore, a width W1 of an opening of the non-fixed groove 11b is greater than a width (i.e., diameter) of the O-ring 10d. The non-fixed groove 11b supports the O-ring 10d on a bottom surface of the non-fixed groove 11b. A depth D1 of the non-fixed groove 11b is smaller than the thickness (i.e., diameter) of the O-ring 10d by a predetermined amount. Therefore, the O-ring 10d protrudes by the predetermined amount (e.g., 1 mm) from the upper surface of the side wall 11 of the chamber body 10a through the opening of the non-fixed groove 11b in a state in which the O-ring 10d is supported on the bottom surface of the non-fixed groove 11b, i.e., in a state in which the O-ring 10d is accommodated in the non-fixed groove 11b,

As shown in FIGS. 5 and 6, the fixed groove 11c accommodates the O-ring 10d and fixes the O-ring 10d in the fixed groove 11c. The fixed groove 11c is, for example, a groove of an angled groove shape, and side surfaces of the fixed groove 11c rise vertically from a flat portion of a bottom surface.

A width W2 of the fixed groove 11c includes an opening and is greater than the width (i.e., diameter) of the O-ring 10d.

In addition, a convex portion 11d protrudes from the center of the bottom surface of the fixed groove 11c in a width direction of the groove (a groove width direction). A top surface of the convex portion 11d is formed to be flat, and a portion other than the convex portion 11d on the groove bottom surface of the fixed groove 11c, i.e., an outer region which is the outside in the groove width direction, is also formed to be flat.

In the fixed groove 11c, the O-ring 10d is supported on the top surface of the convex portion 11d. A height H1 of the convex portion 11d is a height at which the O-ring 10d supported on the top surface of the convex portion 11d protrudes by the predetermined amount from the upper surface of the side wall 11 of the chamber body 10a.

In the fixed groove 11c, the pressing members 100 and 110 are arranged to fix the O-ring 10d. The pressing members 100 and 110 are formed of, for example, a stainless steel material. For at least a member on a vacuum atmosphere side among the pressing members 100 and 110, coating for enhancing corrosion resistance may be performed.

The pressing member 100 is arranged on one side in the groove width direction (left side in FIG. 5) in a region in the fixed groove 11c so as to adjust a position in the groove width direction. Further, the pressing member 100 includes an eaves portion 101. The eaves portion 101 extends toward the other side in the groove width direction (right side in FIG. 5) to form a slit SL through which the inside of the fixed groove 11c communicates with the outside of the fixed groove 11c.

A portion that is higher than the convex portion 11d on a surface of the other side of the pressing member 100 in the groove width direction (right side in FIG. 5) is a tapered surface on which an opening side of the fixed groove 11c protrudes toward the other side in the groove width direction (right side in FIG. 5) to form the eaves portion 101.

Furthermore, a lower surface of the pressing member 100 is formed to be flat so that the pressing member 100 can slide smoothly on the bottom surface of the fixed groove 11c. In addition, in order to prevent the pressing member 100 from falling over during sliding, a lower portion of the pressing member 100 is formed thicker than an upper portion of the pressing member 100, which is formed to be thin because the upper portion has the tapered surface. The height of the pressing member 100 is a height at which the pressing member 100 does not protrude from the upper surface of the side wall 11 of the chamber body 10a in a state in which the pressing member 100 is supported on the bottom surface of the fixed groove 11c.

Similarly, the pressing member 110 is arranged on the other side in the groove width direction (right side in FIG. 5) in a region in the fixed groove 11c so as to adjust a position of the groove width direction. Further, the pressing member 110 includes an eaves portion 111. The eaves portion 111 extends toward the one side in the groove width direction (left side in FIG. 5) to form the slit SL.

A portion that is higher than the convex portion 11d on a surface of the one side of the pressing member 110 in the groove width direction (left side in FIG. 5) is a tapered surface on which the opening side of the fixed groove 11c protrudes toward the one side in the groove width direction (left side in FIG. 5) to form the eaves portion 111.

Furthermore, a lower surface of the pressing member 110 is formed to be flat so that the pressing member 110 can slide smoothly on the bottom surface of the fixed groove 11c. In addition, in order to prevent the pressing member 110 from falling over during sliding, a lower portion of the pressing member 110 is formed thicker than an upper portion of the pressing member 110, which is formed to be thin because the upper portion has the tapered surface. The height of the pressing member 110 is a height at which the pressing member 110 does not protrude from the upper surface of the side wall 11 of the chamber body 10a in a state in which the pressing member 110 is supported on the bottom surface of the fixed groove 11c.

By adjusting the positions of the pressing members 100 and 110 in the groove width direction, a width W3 of the slit SL formed by the eaves portions 101 and 111 is adjustable.

The eaves portions 101 and 111 are formed so as to satisfy the following conditions (1) and (2).
(1) When the pressing member 100 is positioned on the one side in the groove width direction (left side in FIG. 5) in the region on one side in the groove width direction (left side in FIG. 5) in the fixed groove 11c and the pressing member 110 is positioned on the other side in the groove width direction (right side in FIG. 5) in the region on the other side in the groove width direction (right side in FIG. 5) in the fixed groove 11c, the width of the slit SL formed by the eaves portions 101 and 111 is larger than the width of the O-ring 10d.
(2) When the pressing member 100 is positioned on the other side in the groove width direction (right side in FIG. 5) in the region on one side in the groove width direction (left side in FIG. 5) in the fixed groove 11c and the pressing member 110 is positioned on the one side in the groove width direction (left side in FIG. 5) in the region on the other side in the groove width direction (right side in FIG. 5) in the fixed groove 11c, the width of the slit SL formed by the eaves portions 101 and 111 is smaller than the width of the O-ring 10d, and the O-ring 10d is pressed by the eaves portions 101 and 111.

If the width W3 of the slit SL is sufficiently smaller than the O-ring 10d and the pressing members 100 and 110 are fixed, the O-ring 10d can be fixed in the fixed groove 11c by the eaves portions 101 and 111 so that the O-ring 10d does not escape from the fixed groove 11c through the slit SL.

Therefore, the seal structure S has fixing mechanisms 120 and 130 that fix the pressing members 100 and 110 in the fixed groove 11c.

The fixing mechanism 120 for the pressing member 100 has a screw 121 as a protrusion that protrudes to one side in the groove width direction (the left side in FIG. 5) so as to adjust a protrusion length from the pressing member 100, and the aforementioned convex portion 11d. The screw 121 is screwed into a screw hole 102 formed in a surface of one side of the pressing member 100 in the groove width direction, as shown in FIG. 7. By adjusting the engagement length of the screw 121 using a tool T (see FIG. 6), the protrusion length of the screw 121 from the pressing member 100 to one side in the groove width direction (the left side in FIG. 5) is adjustable.

In the fixing mechanism 120, when the protrusion length of the screw 121 increases and the screw 121 protrudes between the pressing member 100 and a side surface of the fixed groove 11c, the pressing member 100 is pressed against a side surface of the convex portion 11d and fixed.

The fixing mechanism 130 for the pressing member 110 has a screw 131 as a protrusion that protrudes to the other side in the groove width direction (the right side in FIG. 5) so as to adjust a protrusion length from the pressing member 110, and the aforementioned convex portion 11d. The screw 131 is screwed into a screw hole (not shown) formed in a surface of the other side of the pressing member 110 in the groove width direction. By adjusting the engagement length of the screw 131 using the tool T (see FIG. 6), the protrusion length of the screw 131 from the pressing member 110 to the other side in the groove width direction (the right side in FIG. 5) is adjustable.

In the fixing mechanism 130, when the protrusion length of the screw 131 increases and the screw 131 protrudes between the pressing member 110 and a side surface of the fixed groove 11c, the pressing member 110 is pressed against a side surface of the convex portion 11d and fixed.

<Example of Method of Installing O-Ring 10d>

Next, an example of a method of installing the O-ring 10d will be described.

### (Step S1: Arrangement of Pressing Members 100 and 110)

For example, first, the pressing members 100 and 110 are arranged in regions on outer sides in the groove width direction in the fixed groove 11c. In this case, the lengths of the screws 121 and 131 connected to the pressing members 100 and 110 protruding toward outer sides in the groove width direction are short, and the slit SL having a width larger than the width of the O-ring 10d is formed by the eaves portions 101 and 111.

### (Step S2: Accommodation of O-Ring 10d)

Next, the O-ring 10d is accommodated in the groove 11a. In the non-fixed groove 11b, the O-ring 10d is accommodated through the opening of the non-fixed groove 11b. In the fixed groove 11c, the O-ring 10d is accommodated through the fixed groove 11c and the slit SL.

### (Step S3: Adjustment of Width of Slit SL and Fixation of Pressing Members 100 and 110)

Thereafter, the width of the slit SL becomes smaller than the width (i.e., diameter) of the O-ring 10d, and the pressing members 100 and 110 are fixed. Specifically, the protrusion lengths of the screws 121 and 131 are increased, and the pressing members 100 and 110 are moved toward an inner side in the groove width direction. Thereby, the width of slit SL becomes smaller than the width of O-ring 10d, and the screws 121 and 131 protrude between the pressing members 100 and 110 and the side surfaces of the fixed groove 11c, so that the pressing members 100 and 110 are pressed against the side surfaces of convex portion 11d and fixed. In this way, the installation of the O-ring 10d is completed.

<Another Example of Method of Installing O-Ring 10d>

Next, another example of the method of installing the O-ring 10d will be described.

### (Step S11: Accommodation of O-Ring 10d)

In this example, first, the O-ring 10d is accommodated in the groove 11a. Through the openings of the non-fixed groove 11b and the fixed groove 11c, the O-ring 10d is accommodated in the non-fixed groove 11b and the fixed groove 11c.

### (Step S12: Arrangement of Pressing Members 100 and 110)

Next, the pressing members 100 and 110 are disposed in regions on outer sides in the groove width direction in the fixed groove 11c. In this case, the lengths of the screws 121 and 131 connected to the pressing members 100 and 110 protruding toward the outer sides in the groove width direction are short.

Then, in the same manner as in step S3 described above, the width of the slit SL becomes smaller than the width (i.e., diameter) of the O-ring 10d, and the pressing members 100 and 110 are fixed. In this way, the installation of the O-ring 10d is completed.

Thus, the order of the process of arrangement of the pressing members 100 and 110 and the process of accommodation of the O-ring 10d is changeable.

The O-ring 10d can be separated by reversing the order of installation of the O-ring 10d.

### Main Effect of Present Embodiment

As described above, in the seal structure S of the present embodiment, after the O-ring 10d is accommodated in the fixed groove 11c that is wider than the O-ring 10d, the slit SL narrower than the O-ring 10d is formed by the eaves portions 101 and 111 of the pressing members 100 and 110, and the pressing members 100 and 110 are fixed, so that the O-ring 10d can be fixed so as not to escape from the groove. In the seal structure S of the embodiment, when the O-ring 10d is accommodated in the groove 11a, it is possible to prevent the existence of the slit SL narrower than the O-ring 10d. Thereby, according to the embodiment, it is possible to suppress the O-ring 10d from being twisted when the O-ring 10d is accommodated in the groove 11a. Therefore, the O-ring 10d can be fixed in the groove 11a without twisting. As a result, the lifespan of the O-ring 10d can be extended.

Furthermore, unlike the embodiment of the present disclosure, when the chamber body 10a is made of ceramics, if a dovetail groove is formed in the chamber body 10a for fixing the O-ring 10d, there is a risk described below. That is, when performing groove machining, there is a risk that a minute part that forms an opening of the dovetail groove will be damaged. Likewise, during installation or separation of the O-ring 10d, there is a risk that the dovetail groove will be damaged. When a material with high hardness, such as a material with high corrosion resistance, is used as the O-ring 10d, there is a risk that the above-mentioned damage will occur, especially during installation or separation of the O-ring 10d. In contrast, in the embodiment, the groove 11a formed in the chamber body 10a is not the dovetail groove, and therefore, even if the chamber body 10a is made of ceramics, there is low possibility that the chamber body 10a will be damaged during groove machining or during installation and separation of the O-ring (including a material with high hardness).

In addition, the seal structure S of the embodiment is sealed by two seal surfaces, i.e., the upper surface of the side wall 11 of the chamber body 10a and the lower surface of the peripheral portion of the cover member 10b, as in the related arts, and the only machining required for the seal surface compared to the related arts is machining of the fixed groove 11c. Therefore, the seal structure S of the embodiment can obtain the same sealing performance as the related arts.

If screw hole machining is performed on a ceramic member, there is a risk that the ceramic member will be damaged. In contrast, in the embodiment, the screw hole machining is not performed on the ceramic member (chamber body 10a) constituting the seal structure S in order to fix the pressing members 100 and 110. In other words, in the embodiment, the pressing members 100 and 110 can be fixed without performing the screw hole processing on the ceramic member (chamber body 10a) which constitutes the seal structure S and may cause damage.

### Modification

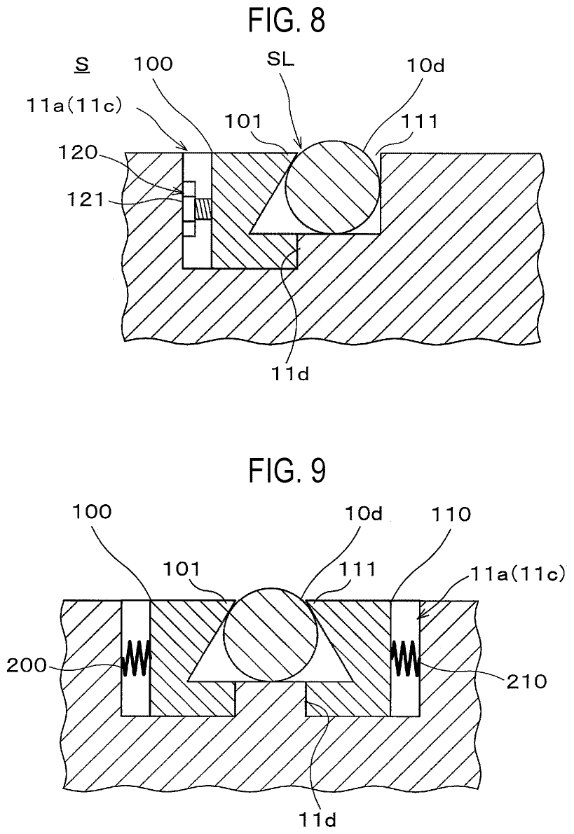

FIG. 8 shows another example of the seal structure. In the seal structure of the above example, the pressing member having the eaves portion has been provided on each of both sides in the groove width direction. However, the pressing member may be provided only on one side in the groove width direction. That is, only one of the pressing members 100 and 110 shown in FIG. 5 may be provided. In the example of FIG. 7, only the pressing member 100 on a reduced-pressure atmosphere side is provided. In this way, when the pressing member is provided only on one side in the groove width direction, the pressing member is desirably provided only on the reduced-pressure atmosphere side among the reduced-pressure atmosphere side and an external atmosphere side. This allows the O-ring 10d to be fixed in the fixed groove 11c in the same way as when the pressing members are provided on both sides in the groove width direction.

In the example of the figure, the slit SL through which the outside and inside of the fixed groove 11c communicate is formed by the eaves portion 101 and a side surface of the fixed groove 11c.

FIG. 9 is a diagram showing another example of the protrusion. In the above example, the protrusions that protrude to the outer sides in the groove width direction so as to adjust the protrusion length from the pressing members 100 and 110 are the screws 121 and 131 that are screwed into the screw holes formed on the outer surfaces of the pressing members 100 and 110 in the groove width direction. As shown in FIG. 9, the protrusions may be springs 200 and 210 connected to the outer surfaces of the pressing members 100 and 110 in the groove width direction as elastic members having elasticity. The springs 200 and 210 may be made of spring steel, nickel alloy, stainless steel, or the like.

Since the springs 200 and 210 do not require performing screw machining on the pressing members 100 and 110, ceramics may be used as the material for forming the pressing members 100 and 110.

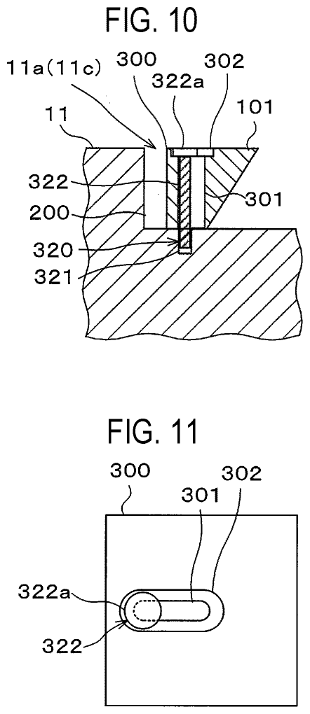

FIGS. 10 and 11 are diagrams showing another example of the fixing mechanism for the pressing member. FIG. 10 is a cross-sectional view of a seal structure having the fixing mechanism for the pressing member of the example, and FIG. 11 is a plan view of the pressing member. Similar to the pressing member 100 shown in FIG. 5, a pressing member 300 in FIG. 10 has the eaves portion 101 extending toward an inner side in the groove width direction. However, as shown in FIG. 10, a fixing mechanism 320 of the pressing member 300 differs from the fixing mechanism 120 of the pressing member 100 in that the fixing mechanism 320 has a screw 322 that penetrates the pressing member 300 in a groove depth direction and is screwed into a screw hole 321 formed in the bottom surface of the fixed groove 11c. In the fixing mechanism 320, the pressing member 300 is fixed by the screw 322.

This configuration is suitably used when the material of the chamber body 10a is a metal material such as stainless steel rather than a ceramic material in order to include performing screw hole processing on the side wall 11 of the chamber body 10a.

As shown in FIG. 11, in order to enable adjustment of the position of the pressing member 300 in the groove width direction in a state in which the screw 322 penetrating the pressing member 300 is screwed into the screw hole 321, a through hole 301 of the pressing member 300 for the screw 322 is a hole that is long in the groove width direction (left and right direction in the figure) when viewed in plan. In addition, a counter boring 302 into which a screw head 322a is inserted is formed on an upper surface of the pressing member 300 so that the screw head 322a of the screw 322 that fixes the pressing member 300 does not protrude from the upper surface of the pressing member 300 and the upper surface of the side wall 11 of the chamber body 10a.

In the example shown in FIG. 2, the fixed groove 11c is provided in a plurality of places on each side of the chamber body 10a. That is, the pressing member arranged in the fixed groove 11c is arranged in a plurality of places on each side of the chamber body 10a. Alternatively, the pressing member may be formed to be longer than, for example, ½ of each side of the chamber body, and one pressing member may be arranged on each side of the chamber body.

Furthermore, the shape of the pressing member is linear when viewed in plan in the example shown in FIG. 6 but may be arc-shaped or L-shaped when viewed in plan. When the shape of the pressing member is arc-shaped or L-shaped when viewed in plan, the fixing mechanism 320 shown in FIGS. 10 and 11 may be used as a fixing mechanism for the pressing member which can easily adjust the position not only in the groove width direction but also in the groove length direction.

Furthermore, the arrangement density of the pressing members on each side of the chamber body 10a is equal between the sides, but the arrangement density of the pressing members on some sides may be higher than that on other sides. Specifically, the arrangement density of the pressing members on a side of the hinge 10c and a side facing the hinge 10c may be higher than that on sides connected to both ends of the side of the hinge 10c. This is because, on the side of the hinge 10c and the side facing the hinge 10c, when the cover member 10b is opened and closed, the O-ring 10d may escape from the groove 11a in a state in which the O-ring 10d is attached to the bottom surface of the peripheral portion of the cover member 10b. By increasing the arrangement density of the pressing members on the side of the hinge 10c and the side facing the hinge 10c, the O-ring 10d can be suppressed from escaping from the groove 11a on the side of the hinge 10c and the side facing the hinge 10c as described above.

In the above example, the groove 11a is formed on the upper surface of the side wall of the chamber body 10a, which is a lower seal surface. Alternatively, the groove 11a may be formed on a lower surface of the peripheral portion of the cover member 10b, which is an upper seal surface.

In the above example, the non-fixed groove 11b is an angled groove, but if the width of the opening of the groove is larger than the width of the O-ring 10d, the non-fixed groove 11b may have a groove shape other than the angled groove, for example, a one-sided dovetail groove shape having a tapered surface only on one side in the groove width direction.

In the above example, the O-ring with a circular cross-sectional shape is used as the seal material, but the seal material may have a cross-sectional shape other than the circular cross-sectional shape. In addition, the shape of the inner side surface of the pressing member in the width direction is appropriately changeable to be suitable for the cross-sectional shape of the seal material.

It is to be noted that the embodiments disclosed herein are exemplary in all respects and are not restrictive. The above-described embodiments may be omitted, replaced, modified, and/or combined in various forms without departing from the scope and spirit of the appended claims. For example, constituent elements of the above embodiments may be arbitrarily combined. From this arbitrary combination, it is needless to say that the operations and effects of the respective constituent elements related to the combination can be obtained, and other operations and other effects obvious to those skilled in the art can be obtained from the description of the present specification.

The effects described herein are illustrative or exemplary only and are not restrictive. That is, the technique of the present disclosure can obtain other effects obvious to those skilled in the art from the description herein in addition to or in place of the above effects.

The following configuration examples are also within a technical scope of the present disclosure.

### (Supplementary Note 1)

According to one aspect of the present disclosure, there is provided a seal structure including:
a groove formed to be wider than a seal material;
a pressing member arranged on one side in a width direction of the groove in a region in the groove so as to adjust a position in the width direction of the groove, and including an eaves portion, which extends toward the other side in the width direction of the groove to form a slit through which an inside of the groove communicates with an outside of the groove and presses the seal material into the groove; and
a fixing mechanism configured to fix the pressing member.

### (Supplementary Note 2)

In the seal structure of Supplementary Note 1, the fixing mechanism includes:
a protrusion configured to protrude to the one side in the width direction of the groove so as to adjust a protrusion length from the pressing member; and
a convex portion configured to protrude from a bottom portion of the groove, and the pressing member is pressed against the convex portion by the protrusion and fixed.

### (Supplementary Note 3)

In the seal structure of Supplementary Note 2, the protrusion is a screw screwed into a screw hole formed in a surface on the one side of the pressing member in the width direction of the groove.

### (Supplementary Note 4)

In the seal structure of Supplementary Note 2, the protrusion is an elastic member having elasticity.

### (Supplementary Note 5)

In the seal structure of Supplementary Note 1, the fixing mechanism comprises a screw configured to penetrate the pressing member in a depth direction of the groove and screwed into a screw hole formed in a bottom surface of the groove, and fixes the pressing member by the screw.

### (Supplementary Note 6)

In the seal structure of any one of Supplementary Notes 1 to 5, the pressing member is arranged on each of the one side and the other side in the width direction of the groove.

### (Supplementary Note 7)

In the seal structure of any one of Supplementary Notes 1 to 5, the pressing member is arranged only on the one side in the width direction of the groove.

### (Supplementary Note 8)

In the seal structure of any one of Supplementary Notes 1 to 7, the pressing member is configured to form the slit having a width wider than a width of the seal material by the eaves portion when the pressing member is positioned on the one side in the width direction of the groove in the region in the groove, and to form the slit narrower than the seal material by the eaves portion when the pressing member is positioned on the other side in the width direction of the groove in the region in the groove and presses the seal material.

### (Supplementary Note 9)

In the seal structure of any one of Supplementary Notes 1 to 7, the groove is formed in a ceramic member.

### (Supplementary Note 10)

According to another aspect of the present disclosure, there is provided a chamber having the seal structure according to any one of Supplementary Notes 1 to 9, wherein the chamber is configured to be capable of reducing pressure and to accommodate a substrate to be processed.

### (Supplementary Note 11)

According to another aspect of the present disclosure, there is provided a substrate processing apparatus including the chamber according to Supplementary Note 10.

### (Supplementary Note 12)

According to another aspect of the present disclosure, there is provided a method of installing a seal material, including:
arranging a pressing member in a region in a groove formed to be wider than a seal material so as to form a slit through which an inside of the groove communicates with an outside of the groove, wherein the region in the groove is on one side in a width direction of the groove, and the pressing member includes an eaves portion extending toward the other side in the width direction of the groove;
accommodating the seal material in the groove;
forming a width of the slit to be smaller than a width of the seal material; and
fixing the pressing member.

According to the present disclosure in some embodiments, it is possible to fix a seal material in a groove without twisting.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A seal structure comprising:
a groove formed to be wider than a seal material;
a pressing member arranged on one side in a width direction of the groove in a region in the groove so as to adjust a position in the width direction of the groove, and including an eaves portion, which extends toward the other side in the width direction of the groove to form a slit through which an inside of the groove communicates with an outside of the groove and presses the seal material into the groove; and
a fixing mechanism configured to fix the pressing member.

2. The seal structure of claim 1, wherein the fixing mechanism comprises:
a protrusion configured to protrude to the one side in the width direction of the groove so as to adjust a protrusion length from the pressing member; and
a convex portion configured to protrude from a bottom portion of the groove, and
wherein the pressing member is pressed against the convex portion by the protrusion and fixed.

3. The seal structure of claim 2, wherein the protrusion is a screw screwed into a screw hole formed in a surface on the one side of the pressing member in the width direction of the groove.

4. The seal structure of claim 3, wherein the pressing member is arranged on each of the one side and the other side in the width direction of the groove.

5. The seal structure of claim 3, wherein the pressing member is arranged only on the one side in the width direction of the groove.

6. The seal structure of claim 3, wherein the pressing member is configured to form the slit having a width wider than a width of the seal material by the eaves portion when the pressing member is positioned on the one side in the width direction of the groove in the region in the groove, and to form the slit narrower than the seal material by the eaves portion when the pressing member is positioned on the other side in the width direction of the groove in the region in the groove and presses the seal material.

7. The seal structure of claim 3, wherein the groove is formed in a ceramic member.

8. The seal structure of claim 2, wherein the protrusion is an elastic member having elasticity.

9. The seal structure of claim 8, wherein the pressing member is arranged on each of the one side and the other side in the width direction of the groove.

10. The seal structure of claim 8, wherein the pressing member is arranged only on the one side in the width direction of the groove.

11. The seal structure of claim 8, wherein the pressing member is configured to form the slit having a width wider than a width of the seal material by the eaves portion when the pressing member is positioned on the one side in the width direction of the groove in the region in the groove, and to form the slit narrower than the seal material by the eaves portion when the pressing member is positioned on the other side in the width direction of the groove in the region in the groove and presses the seal material.

12. The seal structure of claim 8, wherein the groove is formed in a ceramic member.

13. The seal structure of claim 1, wherein the fixing mechanism comprises a screw configured to penetrate the pressing member in a depth direction of the groove and screwed into a screw hole formed in a bottom surface of the groove, and fixes the pressing member by the screw.

14. The seal structure of claim 1, wherein the pressing member is arranged on each of the one side and the other side in the width direction of the groove.

15. The seal structure of claim 1, wherein the pressing member is arranged only on the one side in the width direction of the groove.

16. The seal structure of claim 1, wherein the pressing member is configured to form the slit having a width wider than a width of the seal material by the eaves portion when the pressing member is positioned on the one side in the width direction of the groove in the region in the groove, and to form the slit narrower than the seal material by the eaves portion when the pressing member is positioned on the other side in the width direction of the groove in the region in the groove and presses the seal material.

17. The seal structure of claim 1, wherein the groove is formed in a ceramic member.

18. A chamber having the seal structure according to claim 1, wherein the chamber is configured to be capable of reducing pressure and to accommodate a substrate to be processed.

19. A substrate processing apparatus including the chamber according to claim 18.

20. A method of installing a seal material, the method comprising:
arranging a pressing member in a region in a groove formed to be wider than a seal material so as to form a slit through which an inside of the groove communicates with an outside of the groove, wherein the region in the groove is on one side in a width direction of the groove, and the pressing member includes an eaves portion extending toward the other side in the width direction of the groove;
accommodating the seal material in the groove;
forming a width of the slit to be smaller than a width of the seal material; and
fixing the pressing member.
